(19) United States
(12) Patent Application Publication
(10) Pub. No.: US 2026/0269171 A1
(43) Pub. Date: Sep. 10, 2026

(54) MODULAR METROLOGY APPARATUS FOR INTERCHANGEABLE PROCESS MODULES

(71) Applicant: Carl Zeiss SMT GmbH, Oberkochen (DE)

(72) Inventors: Patrick Hengsberger, Sontheim-Brenz (DE); Thomas Korb, Schwaebisch Gmuend (DE)

(21) Appl. No.: 19/666,741

(22) Filed: May 4, 2026

Related U.S. Application Data
(63) Continuation of application No. PCT/EP2024/079809, filed on Oct. 22, 2024.

(30) Foreign Application Priority Data
Nov. 6, 2023 (DE) 102023130647.2

(51) Int. Cl. H01J 37/16; G01B 11/14; H01J 37/28

(52) U.S. Cl. CPC H01J 37/16; G01B 11/14; H01J 37/28; H01J 2237/24578; H01J 2237/2801

(57) ABSTRACT

A modular metrology apparatus comprises a vacuum chamber housing with an opening having a mechanical interface for sealed attachment of modular adapters. A sample stage inside the vacuum chamber positions a sample for processing. One or more charged-particle scanning systems scan particle beams across the sample. The mechanical interface enables integration of removable interchangeable modular adapters containing different configurations of process modules. The process modules are sealed within adapters and extend from outside to inside the vacuum housing towards the sample stage. Modular adapters are interchangeable to reconfigure installed process modules. Configurations may include scanning electron beams, focused ion beams, interferometers, detectors, and other process modules. The modular architecture provides a configurable mechanical framework to optimize the metrology apparatus by swapping adapters with customized sets of process modules.

### CROSS-REFERENCE TO RELATED APPLICATIONS

This application is a continuation of and claims benefit under 35 U.S.C. § 120 from PCT application PCT/EP2024/079809, filed on Oct. 22, 2024, which claims priority from German patent application 10 2023 130 647.2, filed on Nov. 6, 2023. The entire contents of each of these earlier applications are incorporated herein by reference.

### TECHNICAL FIELD

Various examples generally relate to metrology systems. Various examples particularly relate to a modular metrology apparatus integrating multiple process modules configured for different operation modalities.

### BACKGROUND

In modern metrology applications, a variety of techniques are employed for material characterization, defect inspection, and sample measurement. Instruments such as Scanning Electron Microscope (SEM), Focused Ion Beam (FIB), Laser-Induced Fluorescence (LIF), and Gas Injection System (GIS) are capable of performing specialized tasks, but their operation often imposes limitations. For instance, the current configurations of SEM systems typically offer a working distance (WD) that is not reduced enough to meet the needs for higher resolution. Moreover, the cutting efficiency of FIB systems is often compromised due to design constraints. For example, a dual beam FIB-SEM system combines both capabilities, but locations of the electron and ion columns relative to each other and working distance to the sample are limited by mechanical constraints and cannot be altered after system integration. From documents DE 10 2021 128 117 A1 and DE 10 2021 110 948 A1 metrology systems are known.

Adapting a conventional metrology apparatus to changing requirements is impractical and requires venting, realignment, and requalification. As a result, often additional systems must be purchased to satisfy diverging inspection requirements.

### SUMMARY

Accordingly, a need exists for advanced metrology systems that mitigate or reduce at least some of the above-identified drawbacks. In particular, a need exists for a metrology apparatus employing at least one charged-particle scanning system that can be easily adapted to changing requirements.

This need is met by the features of the independent claims. The features of the dependent claims define embodiments.

It is to be understood that the features mentioned above and those yet to be explained below may be used not only in the respective combinations indicated, but also in other combinations or in isolation without departing from the scope of the invention.

A modular metrology apparatus is provided, which is configured to process a sample in a vacuum chamber. The vacuum chamber is formed by a vacuum chamber housing having an opening with a mechanical interface configured for attachment of a modular adapter. The modular metrology apparatus further comprises a sample stage located inside the vacuum chamber housing. The modular metrology apparatus further comprises at least one charged-particle scanning system, each of the at least one charged-particle scanning system being configured for scanning a respective beam of charged particles across the sample stage.

The opening may be located, for example, on a side of the vacuum chamber housing that is opposite to the sample stage. The opening may be a round opening (i.e., have a circular shape) or may comprise edges with at least partly straight and/or angled portions. The mechanical interface may be configured for sealed attachment of one of a variety of modular adapters. In various examples, the claimed modular metrology apparatus may or may not comprise the modular adapter. The modular adapter may be formed such that it can be releasably inserted partially into the opening from the top side of the vacuum chamber housing but cannot pass fully through the opening due to a larger dimension in the x-y-plane compared to the opening on the outside. When attached, a modular adapter may extend partially through the opening along the z-axis into the sealed inner space of the metrology apparatus. The modular adapter may extend from the opening of the vacuum chamber housing along the z-axis in both the positive and negative direction. It may extend over the top outside surface of the vacuum chamber housing by more than the thickness or twice the thickness of the vacuum chamber housing. It may extend to the inside of the vacuum chamber from over the inside surface of the vacuum chamber housing by more than 20%, or 30%, or 50% of the distance from the vacuum chamber housing to the sample stage along the z-axis.

A modular adapter may accommodate one or more process modules, for example two or more, or three or more, or four or more process modules, in a specific spatial configuration to enable desired operating modalities. The at least one charged-particle scanning system may comprise one of the at least one process modules. In other words, the at least one process modules may comprise a process module that comprises at least part of the charged-particle scanning system, and optionally one or more further process modules that provide further processing operation modalities. The vacuum chamber housing may comprise the opening, wherein the mechanical interface is formed at the edge along, particularly around, the opening. The modular metrology apparatus may be configured for sealed attachment of a modular adapter. The modular metrology apparatus may be configurable for sealed attachment of at least one, or various, e.g., at least two or three different modular adapters. The modular adapters may comprise a corresponding mechanical interface, i.e., that corresponds to the mechanical interface of the vacuum chamber opening. It will be understood that the mechanical interfaces of the vacuum chamber opening, and the modular adapter provide for sealed attachment between the vacuum chamber housing and the modular adapter. The mechanical interfaces may comprise corresponding mechanical attachment and/or sealing structures, which correspond to each other such that they enable the sealed attachment. The mechanical interface may extend along the opening and/or around the opening, specifically around the complete perimeter of the opening.

In other words, the modular metrology apparatus comprises a vacuum chamber housing that forms an enclosed structure with an interior space together with the modular adapter. The vacuum chamber housing comprises an opening on one side that allows access to the interior space. Around this opening a mechanical interface may be located that enables removable attachment of interchangeable modular adapters. This mechanical interface may provide a sealed connection to maintain vacuum conditions when a modular adapter is installed. Within the vacuum chamber housing is a sample stage on which a specimen or sample can be mounted for analysis or processing. The sample stage may provide adjustable positioning of the sample within the interior space of the vacuum chamber housing. By moving the sample stage, the position of the sample may be controlled in three dimensions. In other examples, the sample stage may also only be movable in a plane, i.e., in x-y-direction.

In various examples, the modular metrology apparatus employs a charged-particle scanning system. In some examples, this may refer to the fact that the modular metrology apparatus comprises a specific process module, specifically an electron microscope process module, comprising an electron microscope source column capable of scanning a focused beam across the sample. Accordingly, the at least one process module may comprise at least part of the charged-particle scanning system. At least one such charged-electron scanning system may be included, but also multiple charged-particle scanning systems can be included. The charged-particle beam can comprise for example electrons or ions. Each scanning system can independently scan its respective particle beam across the sample stage surface.

In general, a modular adapter may refer to a mechanical component that is configured for receiving, or guiding or holding various process modules. A modular adapter refers to an interchangeable component that physically interfaces with the vacuum chamber housing of the metrology apparatus. The primary purpose of the modular adapter is to integrate and provide mounting points for one or more process modules. The modular adapter may be arranged in the opening of the vacuum chamber housing. Accordingly, the at least one process module may be arranged in the opening or may extend through the opening in the vacuum chamber housing. The modular adapter includes ports, connections, alignment features, and other means to receive process modules, while being exchangeable to the vacuum chamber housing. When attached to the edge of the opening in the vacuum chamber housing, the modular adapter allows process modules to extend into the interior vacuum space and interact with samples on the stage.

Modular adapters can be exchanged to allow different combinations of process modules to be configured. This provides flexibility to optimize the metrology apparatus by swapping modular components tailored for particular analytical needs. The adapter acts as the main intermediary between the vacuum housing and customized process modules. The modular architecture with exchangeable adapters allows the overall system to be adapted and reconfigured for diverse inspection and metrology applications. The modular adapter provides the interface to integrate this configurability and modularity.

In various examples, the charged-particle scanning system may comprise or be integrated into a process module that is sealed and fixed in, and extends through, the modular adapter and opening into the vacuum chamber housing. In some examples, the at least one process module can be a part of the charged-particle scanning system. For example, such a charged-particle scanning system process module could comprise an electron column or ion column assembly. This process module may extend through a socket or port in the modular adapter, extending from outside the vacuum housing into the interior vacuum space. The portion of the scanning system inside the vacuum could include for example the beam generation components like sources, lenses, detectors, etc. The exterior portion outside vacuum could contain electronics, pumps, controllers, and peripheral components that do not need to be under vacuum.

The modular adapter may be configured to hold the at least one process module in different spatial configurations, e.g., different angles or positions relative to the modular adapter and/or relative to another process module, as will be described in the following in more detail. The modular design allows different scanning systems to be interchanged at the opening in the vacuum chamber. Various different modules may be attached to the vacuum chamber housing to reconfigure the metrology apparatus for desired analysis capabilities. All modules connect securely to the mechanical interface to maintain vacuum integrity during operation. The process modules may be fixedly attached to the vacuum chamber housing or may be releasably attached.

In other words, the mechanical interface may be configurable to receive and attach to various modular adapters. This may be achieved by providing the mechanical interface configured to attach and seal to corresponding mechanical interfaces of the modular adapters. For example, the mechanical interface may extend around the perimeter of the opening in the vacuum chamber housing. By extending around the periphery of the opening, the mechanical interface provides a continuous mounting surface to which a modular adapter can be secured and sealed. The modular adapter may be hermetically sealed in the opening. The modular adapter may comprise one or more process modules designed to interact with or process the sample within the vacuum chamber. By configuring the mechanical interface around the opening, different modular adapters containing various process modules can be exchanged and implemented on the metrology apparatus. Therefore, the mechanical interface surrounding the opening in the vacuum chamber housing provides a configurable mounting point for integrating interchangeable modular adapters to reconfigure the metrology apparatus.

The mechanical interface may utilize various types of connectors to enable attachment of modular adapters, as will be described in more detail with reference to the figures. For example, the mechanical interface could employ quick-release clamps, screws, latches, or other fastening mechanisms to secure a modular adapter. These removable fasteners allow adapters to be exchanged by uninstalling and reinstalling the clamps or screws. The mechanical interface may also utilize gaskets or seals between the surfaces of the opening and the adapter. This creates an air-tight junction to maintain vacuum conditions within the chamber. The gasket materials could include elastomers, metals, or other materials compatible with high vacuum. Additionally, the mechanical interface may include alignment guides such as pins, shoulders, or other registers. These guides enable precise positioning of the modular adapter relative to the interior of the vacuum chamber. Proper alignment helps ensure the process modules integrate correctly with the sample stage and beam optics. In various examples, the connection itself could involve a flange, lip, or other junction where the adapter and vacuum chamber engage with each other. This junction can be designed for force-fit, form-fit, friction-fit, or material bonding to create a solid attachment, as will be described in detail in the following. A vacuum-tight seal is provided between the modular adapter and the vacuum chamber housing.

The modular adapter may be constructed as an integral one-piece component containing all the interfaces and sockets for mounting the at least one process modules. In this approach, the adapter would be a single complete unit that integrates multiple modules. Alternatively, the modular adapter could comprise two or more separate segments or pieces that combine to form the complete adapter assembly. For example, process module sockets may be distinct removable blocks that attach to a base adapter structure. This allows adapters to be reconfigured by swapping different socket blocks. The sockets and ports for receiving individual process modules could similarly be integral parts of the adapter. Or the sockets could be distinct modular components that attach to the adapter to enable flexible socket configurations. A hybrid approach is also possible, where some portions like vacuum seals and main structural elements are integrated while module sockets remain separate.

### BRIEF DESCRIPTION OF DRAWINGS

These and other aspects of the invention will be appreciated and understood by those skilled in the art from the detailed description of the preferred embodiments and the following drawings in which like reference numerals refer to like elements.

FIG. 1 schematically illustrates a modular metrology apparatus including a SEM process module and a FIB process module, according to various examples.

FIG. 2 schematically illustrates a modular metrology apparatus including various further process modules for processing a sample, according to various examples.

FIG. 3 schematically illustrates a modular metrology apparatus including a SEM process module, a FIB process module, and a Laser Interferometer, according to various examples.

FIG. 4 schematically illustrates the working distance of the modular metrology apparatus of FIG. 3, according to various examples.

FIG. 5 schematically further illustrates the working distance of the modular metrology apparatus of FIGS. 2 and 3 with regard to a reference mirror of the Laser Interferometer, according to various examples.

FIG. 6 schematically illustrates a modular adapter, wherein a reference mirror associated with a Laser Interferometer is recessed within the modular adapter, according to various examples.

FIG. 7 schematically illustrates the modular metrology apparatus of FIG. 3 comprising a different modular adapter with a different configuration of the SEM and FIB process modules, and the Laser Interferometer with recessed reference mirror, according to various examples.

FIG. 8 schematically illustrates the working distance of the modular metrology apparatus of FIG. 7, according to various examples.

FIG. 9 schematically illustrates a modular metrology apparatus comprising a modular adapter with a further process module configuration, according to various examples.

FIG. 10 schematically illustrates a modular metrology apparatus comprising a modular adapter with a further process module configuration, according to various examples.

FIG. 11 schematically illustrates a modular metrology apparatus comprising a modular adapter with a further process module configuration, according to various examples.

FIG. 12 schematically illustrates a mechanical interface between a vacuum chamber housing and a modular adapter, according to various examples.

FIG. 13 schematically illustrates a further mechanical interface between a vacuum chamber housing and a modular adapter, according to various examples.

FIG. 14 schematically illustrates a further mechanical interface between a vacuum chamber housing and a modular adapter, according to various examples.

FIG. 15 schematically illustrates a modular metrology apparatus comprising SEM and FIB process modules and a deflection unit integrated into the modular adapter, according to various examples.

### DETAILED DESCRIPTION

In the following, embodiments of the invention will be described in detail with reference to the accompanying drawings. It should be understood that the following description of embodiments is not to be taken in a limiting sense. The scope of the invention is not intended to be limited by the embodiments described hereinafter or by the drawings, which are taken to be illustrative examples of the general inventive concept. The features of the various embodiments may be combined with each other, unless specifically noted otherwise.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Some examples of the present disclosure generally provide for a plurality of modules or other electrical devices of a modular metrology apparatus. All references to the modules and other electrical devices and the functionality provided by each are not intended to be limited to encompassing only what is illustrated and described herein. While particular labels may be assigned to the various modules or other electrical devices disclosed, such labels are not intended to limit the scope of operation for the modules and the other electrical devices. Such modules and other electrical devices may be combined with each other and/or separated in any manner based on the particular type of mechanical and/or electrical implementation that is desired. It is recognized that any process module or other electrical device disclosed herein may include any number of microcontrollers, a graphics processor unit (GPU), integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a program code that is embodied in a non-transitory computer readable medium programmed to perform any number of the functions as disclosed. Hereinafter, techniques of imaging and processing microscopic samples using charged-particle scanning systems such as SEMs and FIBs are disclosed. It is to be understood that the described techniques may be applied to any metrology apparatus that employs a vacuum chamber.

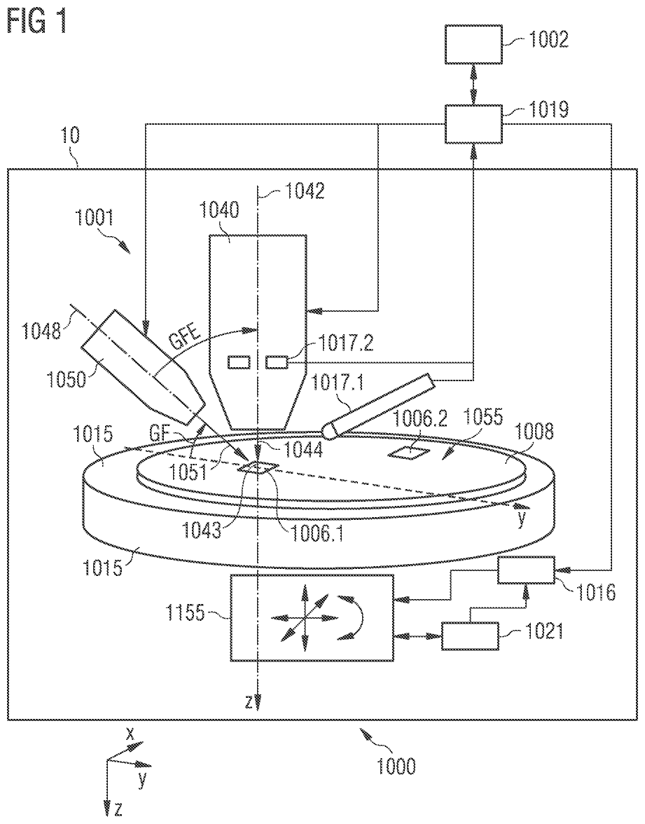

FIG. 1 schematically illustrates a dual beam modular metrology apparatus 1000 including an SEM process module 5040 and a FIB process module 5050, in which the techniques according to the present disclosure can be applied.

As can be seen in FIG. 1, the metrology apparatus 1000 comprises a wafer inspection system configured for a slice- and imaging method with a dual beam configuration. Processing a sample in the metrology apparatus is typically performed in a sealed environment, such as a process chamber, specifically in a vacuum chamber formed by a vacuum chamber housing 10, which his schematically depicted around the metrology apparatus 1000. Process modules comprising for example SEM-column 5040, FIB-column 5050 and particle detector 1017 may extend from an exterior of the vacuum chamber through the vacuum chamber housing 10 to the interior of the vacuum chamber housing 10 according to the techniques of the present disclosure.

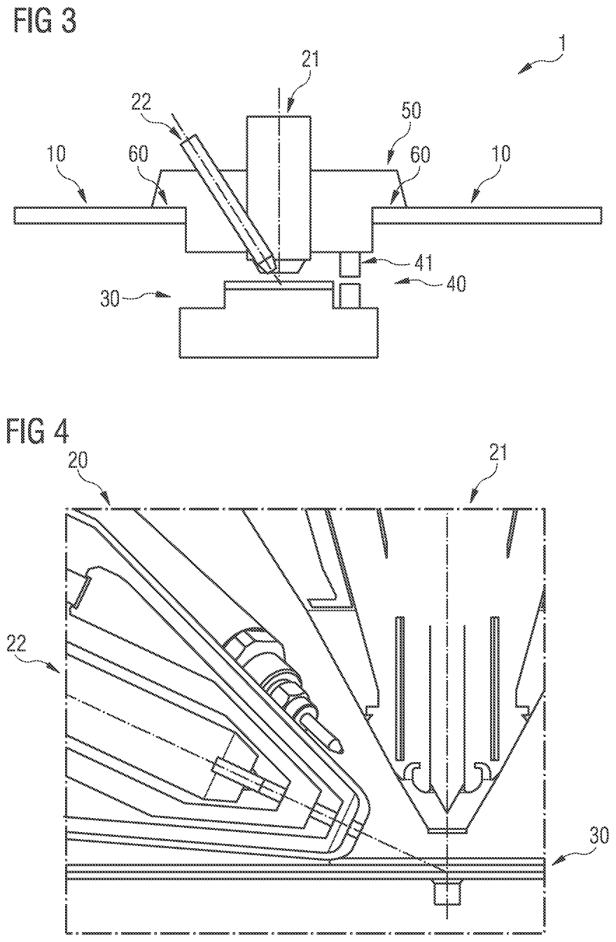

For a wafer 1008, several measurement sites, comprising measurement sites 1006.1 and 1006.2, are defined in a location map or inspection list generated from an inspection tool or from design information. The wafer 1008 is placed on a wafer support table 1015 (corresponding to the sample stage 164). The wafer support table 1015 is mounted on a stage 1155 with actuators and position control 1021. Actuators and means for precision control 1021 for a wafer stage 1155 such as laser interferometers are known in the art. A control unit 1016 receives information about the actual position of the wafer stage 1155 and is configured to control the wafer stage 1155 and to adjust a measurement site 1006.1 of the wafer 1008 at the intersection point 1043 of the dual-beam device 1001. The dual beam device 1001 is comprising a FIB column 1050 with a FIB optical axis 1048 and a charged particle beam (CPB) imaging system 1040 (e.g., SEM or HIM; cf. FIG. 3: charged-particle scanning microscope 160) with optical axis 1042. At the intersection point 1043 of both optical axes of FIB and CPB imaging system, the wafer surface 1055 is arranged at a slant angle GF to the FIB axis 1048. FIB and CPB co-observe the sample. FIB axis 1048 and CPB imaging system axis 1042 include an angle GFE. In the coordinate system of FIG. 7, the normal to the wafer surface 15 is given by the z-axis. The focused ion beam (FIB) 1051 is generated by the FIB-column 1050 and is impinging under angle GF on the surface 1055 of the wafer 1008. Slanted cross-section surfaces may be milled into the wafer by ion beam milling at the inspection site 1006.1 under approximately the slant angle GF at a predetermined y-position, which is controlled by the stage 1155 and position control 1021. In the illustrated example, the slant angle GF is approximately 30°. The actual slant angle of the slanted cross-section surface can deviate from the slant angle GF by up to 1° to 4° due to the beam divergency of the focused ion beam, for example a Gallium-Ion beam, or due to variable material properties with respect to milling along the cross-section surface. With the charged particle beam imaging system 1040, images of the milled surfaces are acquired. In the example of FIG. 7, the charged particle beam imaging system 1040 is arranged with its charged particle beam 1044 perpendicular to the wafer surface 1055 and parallel to the z-axis. In other configurations, the optical axis 1042 of the charged particle beam imaging system 1040 is arranged at an angle to the z-axis.

During imaging, a beam of charged particles 1044 is scanned by a scanning unit of the charged particle beam imaging system 1040 along a scan path over a cross-section surface of the wafer at measurement site 106.1, and secondary particles as well as backscattered particles are generated. Particle detector 1017.1 and optional internal particle detector 1017.2 collect at least some of the secondary particles and/or backscattered particles and communicate the particle count with a control unit 1019. Other detectors for other kinds of interaction products such as x-rays or photons may be present as well. Control unit 1019 is in control of the charged particle beam imaging column 1040 and of the FIB column 1050 and connected to a control unit 1016 to control the position of the wafer mounted on the wafer support table 1015 via the wafer stage 1155. Operation control unit 1002 communicates with control unit 1019, which triggers placement and alignment for example of measurement site 1006.1 of the wafer 1008 at the intersection point 1043 via wafer stage movement and triggers repeatedly operations of FIB milling, image acquisition and stage movements. Control unit 1019 and operation control unit 1002 comprises a memory for storing instructions in form of software code and at least one processer to execute during operation the instructions. A memory is further provided to store digital image data. Operation control unit 1002 may further comprise a user interface or an interface to other communication interfaces to receive instructions, prior information and to transfer inspection results.

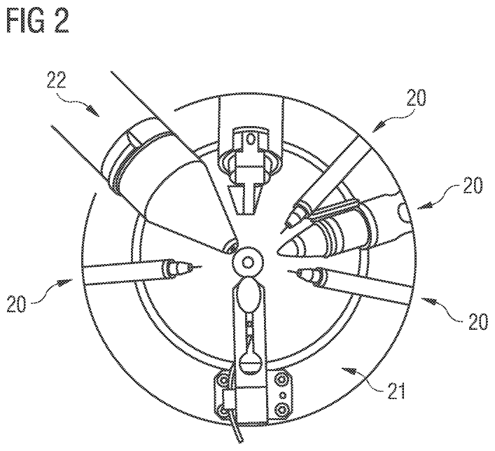

FIG. 2 schematically illustrates various process modules 20, 21, 22 of a modular metrology apparatus for processing a sample, which can be anchored in a modular adapter according to the techniques of the present disclosure.

The metrology apparatus is shown with an SEM process module 21 and a focused-ion beam process module 22 among other process modules 20, which are pointing towards a sample stage 30. The process modules can be arranged within a vacuum chamber of the modular metrology apparatus, wherein the techniques described in the present disclosure can be applied for anchoring the process modules 20, 21, 22 using a modular adapter (not shown), and not separately, in a vacuum chamber housing (not shown) of the metrology apparatus. In particular, in FIB-SEM applications, the available space in the immediate vicinity of the scan region is limited, since additional devices (e.g., precursor gas sources or micromanipulators or detectors) should be positioned as close to the sample as possible. A modular adapter sealed within the vacuum chamber housing provides a mechanical framework for integrating multiple process modules in a compact layout optimized for operation near the sample stage. The modular adapter allows in particular the SEM column 21, which may also be referred to as SEM process module, and FIB column 22, which may also be referred to as FIB process module, to be positioned in close proximity to a sample, along with other ancillary process modules like a gas injection system and micromanipulator. The modular metrology apparatus enables flexible configurations via exchangeable modular adapters tailored to integrate multiple analytical techniques.

FIG. 3 schematically illustrates a modular metrology apparatus 1 including a SEM process module 21, a FIB process module 22, and a Laser Interferometer, according to various examples. As can be seen in FIG. 3, the modular metrology apparatus 1 comprises a vacuum chamber housing 10 with an opening, a sample stage 30, a modular adapter 50, a SEM process module 21, a FIB process module 22, and a laser interferometer system 40 with a reference mirror 41.

The modular adapter 50 is located within the opening of the vacuum chamber housing 10, and is attached to the vacuum chamber housing 10 by a mechanical interface 60 extending along the opening of the vacuum chamber housing 10. Accordingly, parts of the vacuum chamber housing 10 are schematically depicted the right and left of the modular adapter and positioned around the modular adapter 50 such that the modular adapter 50 is enclosed by the edges of the opening, for forming and sealing an enclosed vacuum chamber that houses the sample stage 30 and at least part of the process modules 21, 22. Within the vacuum chamber housing is the sample stage 30, where the sample to be analyzed is mounted. The modular adapter 50 is positioned around the SEM and FIB process modules 21, 22, which extend through the modular adapter 50 and are positioned and sealed within the modular adapter 50. It has ports through which the SEM 21 and FIB 22 modules extend.

In the example of FIG. 3, the FIB process module 21 and SEM process module 22 are arranged in a specific spatial configuration, defined by the modular adapter 50. The SEM process module 21 is positioned in the center and extends upwards in a vertical direction (along the z-axis) through the modular adapter 50 and points down towards the sample stage 30. On one side of the SEM process module 21 is the FIB process module 22. It also extends through the modular adapter to direct its beam at the sample stage 30, and is angled relative to the z-axis and SEM process module longitudinal axis. At the bottom is the laser interferometer system 40, with its reference mirror 41. This allows precise distance measurement between the adapter and sample stage.

Different modular adapters 50 comprising different configurations of process modules, i.e., different spatial configurations and/or different modular adapters 20 can be attached to the vacuum chamber housing 10. For example, another modular adapter 50 may provide different (optionally adaptable) configurations, i.e., orientations and/or positions, of the process modules 21, 22 relative to each other and the modular adapter 50, as will be explained with regard to the following figures in more detail.

The vacuum chamber housing 10 provides an opening with a standardized mechanical interface 60 to integrate various modular adapters 50 having a corresponding mechanical interface in a flexible, interchangeable manner.

FIG. 4 schematically illustrates the working distance of the modular metrology apparatus 1 of FIG. 3, according to various examples.

The FIB process module 22 is depicted at an angle relative to the z-axis, pointing towards the sample stage 30. The angular orientation of the FIB module 22 helps to reach a common coincidence point on the sample stage 30 with the SEM process module 21. A further process module 20 is shown arranged around the SEM and FIB columns 21, 22. The presence of additional process modules in close proximity to the columns constrains the available space surrounding the sample stage 30. The SEM process module 21 is oriented vertically along the z-axis, which is perpendicular to the sample stage 30. Due to the tight configuration of multiple process modules, the working distance between the SEM column tip and the sample stage 30 is limited by mechanical constraints. As can be taken from FIG. 4, The minimum achievable working distance is restricted by potential collisions or interference between the angled FIB column 22 and the vertically oriented SEM column 21, and the further process module 20, as well as the beam diameters of the SEM and FIB process modules. Oftentimes, the working distance between column tip and sample is a key parameter that should be minimized for SEM and/or FIB process modules, however, is limited by mechanical restrictions.

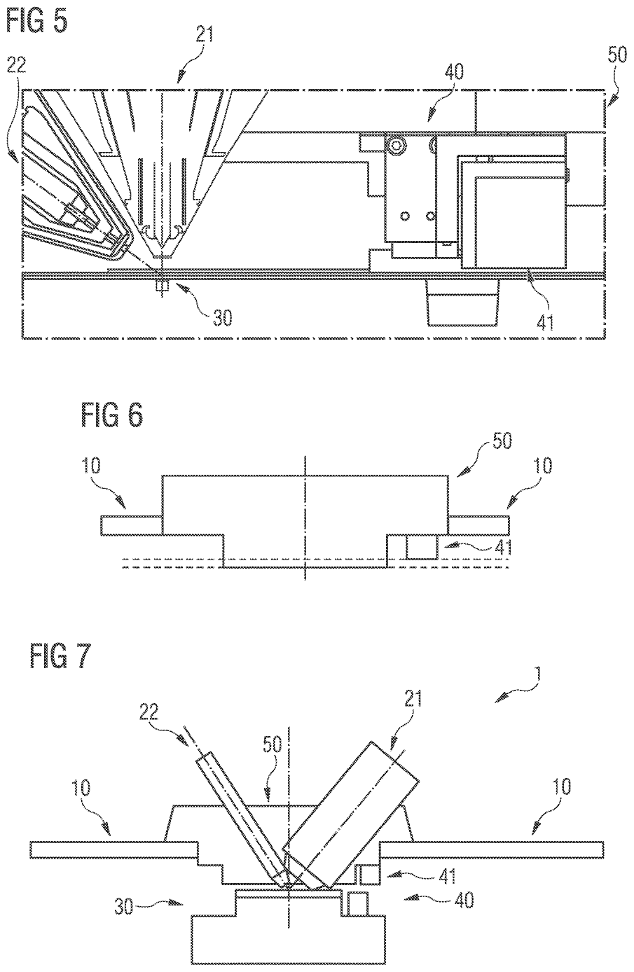

FIG. 5 schematically further illustrates the working distance of the modular metrology apparatus 1 of FIGS. 2 and 3 with regard to a reference mirror 41 of the Laser Interferometer System 40, according to various examples.

FIG. 5 further illustrates the constraint on minimum working distance imposed by the laser interferometer system 40 integrated into the modular metrology apparatus. Similar to FIG. 4, the SEM process module 21 and FIB process module 22 are shown anchored into the modular adapter 50 and directed at the sample stage 30. Additionally, a laser interferometer system 40 is incorporated into the modular adapter 50 and/or SEM process module 21 assembly. The laser interferometer system 40 includes a reference mirror 41 mounted to the modular adapter 50 and/or SEM process module 21. The bottom reflective surface of the reference mirror 41 is used for interference measurements. The distance between the reference mirror 41 and the sample stage 30 restricts how close the SEM and FIB column tips can be positioned to the sample stage.

This reflective bottom surface of the reference mirror 41 is positioned lower, i.e., closer to the sample stage 30, than the lower tip of the SEM process module 21. Because the reference mirror 41 is extended closer to the sample stage 30 than the SEM tip, it imposes a constraint on the minimum working distance between the SEM tip and sample stage.

FIG. 6 schematically illustrates a modular adapter 50 mounted to a vacuum chamber housing 10, wherein a reference mirror 41 associated with a Laser Interferometer 40 is recessed within the modular adapter 50.

The reference mirror 41 is shown positioned at a recessed location within the modular adapter 50, set back from the lower exterior boundary/edge of the modular adapter 50, as indicated by the dashed lines. This illustrates how recessing and positioning components within the adapter can provide more flexibility. However, the integrated nature of the modular design means all elements must be considered holistically when determining minimum working distances. FIG. 7 schematically illustrates the modular metrology apparatus 1 of FIG. 3 comprising a different modular adapter 50 with a different configuration of the SEM and FIB process modules 21, 22, and the Laser Interferometer 40 with recessed reference mirror 41, according to various examples.

FIG. 7 schematically illustrates the modular metrology apparatus 1 of FIG. 3 with a different modular adapter 50 and process module configuration compared to FIG. 3. Similar to FIG. 3, the apparatus includes a SEM process module 21, FIB process module 22, and further a Laser Interferometer 40 with a recessed reference mirror 41. However, in FIG. 7, the SEM process module 21 is shown in a tilted orientation relative to the z-axis, rather than vertical. This tilted orientation of the SEM column 21 and the recessed reference mirror 41 allow a closer working distance between the SEM tip and sample stage 30.

FIG. 8 schematically illustrates the working distance of the modular metrology apparatus of FIG. 7, according to various examples.

As can be seen schematically in FIG. 8, in this and various other examples described with reference to the other drawings, the SEM and/or FIB working distance to sample stage can be less than 5 mm. The ability to tilt the SEM column, provided by the modular adapter, enables faster and further reduction of the minimum working distance. This demonstrates how exchanging modular adapters can change positioning of process modules relative to the sample stage. FIG. 7 shows how interchangeable adapters can facilitate flexible positioning of process modules to reduce working distance.

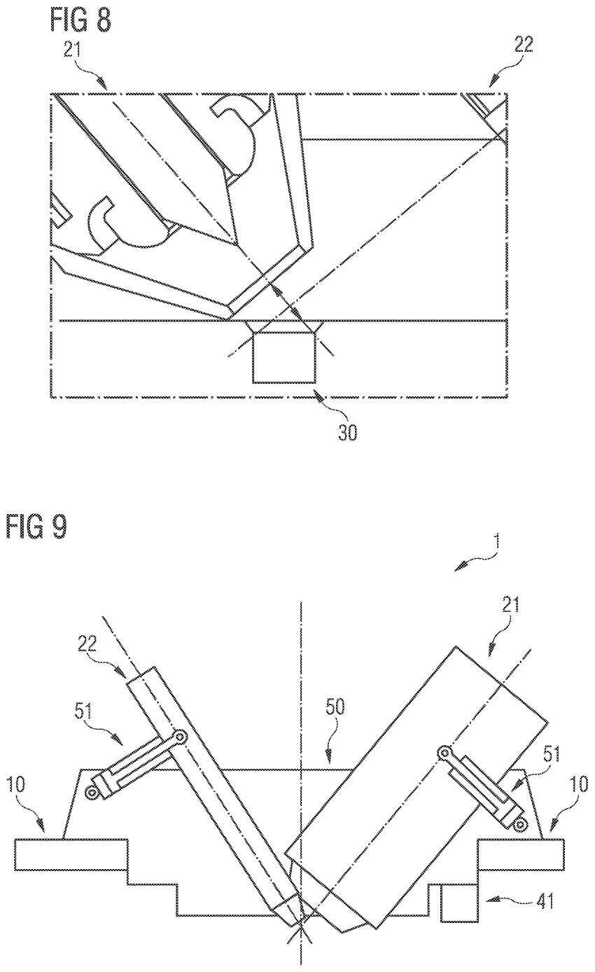

FIG. 9 schematically illustrates a modular metrology apparatus 1 comprising a modular adapter 50 with a further pivotable process module configuration, according to various examples.

As in previous figures, the modular adapter 50 is shown attached via a mechanical interface to the vacuum chamber housing 10. The mechanical interface between the adapter 50 and housing 10 is a sealed connection. In this configuration, the process modules 22 and 21 are pivotally movable relative to the modular adapter 50 by actuators 51. The actuators 51 enable angular positioning of the process modules by rotating them about pivot axes relative to the sample stage 30 and/or modular adapter 50. This allows flexibility in orienting the modules to optimize the angle of incidence on the sample stage 30. The reference mirror 41 of the Laser Interferometer is recessed as described above. The process modules 22 and 21 can be independently pivoted and locked into position using the integrated actuators 51.

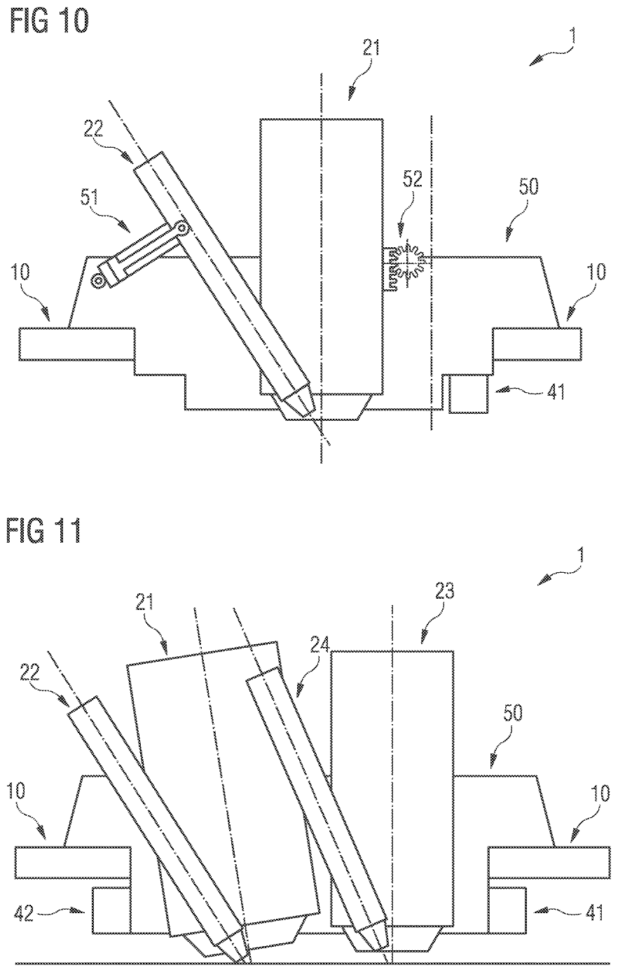

FIG. 10 schematically illustrates a modular metrology apparatus 1 with a modular adapter 50 having a further configurable process module configuration or arrangement, according to various examples.

In this configuration, the FIB process module 22 is pivotally movable relative to the modular adapter 50 by an integrated actuator 51. This allows angular positioning of the FIB module 22 by rotating it about a pivot axis by a further actuator 52. In particular, the SEM process module 21 is translationally movable relative to the modular adapter 50 and/or sample stage 30 in the vertical direction by a linear actuator 52. This enables positioning of the SEM module 21 closer to or further from the sample stage 30. The modular adapter 50 incorporates both a rotary actuator 51 to pivot the FIB module 22, and a linear actuator 52 to translate the SEM module 21. The reference mirror 41 of the Laser Interferometer is recessed as described above. This demonstrates how different types of actuators can be integrated into the adapter 50 to provide flexibility in positioning different process modules independently. Both angular and linear precision adjustment is possible.

FIG. 11 schematically illustrates a modular metrology apparatus 1 comprising a modular adapter 50 with a further process module configuration, according to various examples.

As can be seen in FIG. 11, the modular metrology apparatus 1 with a modular adapter 50 is configured to accommodate multiple similar process modules 21, 22, 23, and 24.

The adapter 50 integrates a first SEM process module 21 and a second SEM process module 23. It also incorporates a first FIB process module 22 and a second FIB process module 24. Additionally, two recessed reference mirrors 41 and 42 associated with laser interferometer systems are shown. The first reference mirror 41 is associated with the first SEM module 21. The second reference mirror 42 is associated with the second SEM module 23. By integrating multiple SEM and FIB columns along with multiple recessed reference mirrors, the modular architecture enables a multi-beam metrology apparatus. The adapter 50 allows duplication of process modules and flexible positioning of components. Multiple electron and ion beam columns enable advanced multi-modality inspection and processing. This demonstrates the versatility of the modular adapter-based architecture to accommodate multi-tool configurations through customized adapters.

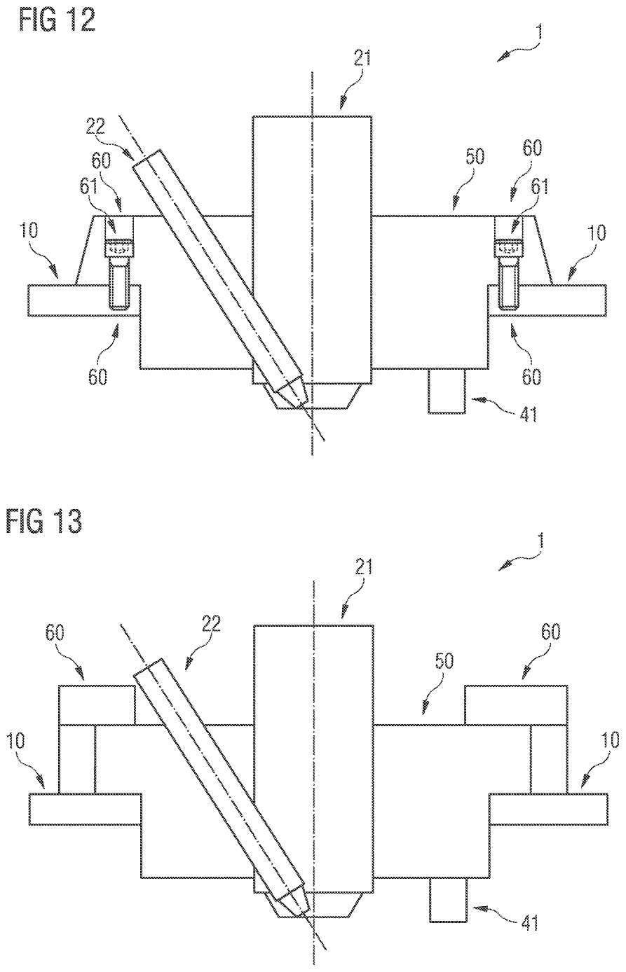

FIG. 12 schematically illustrates a mechanical interface 60 between a vacuum chamber housing 10 and a modular adapter 50, according to various examples.

As can be seen in FIG. 12, a mechanical force-fit interface between a vacuum chamber housing 10 and a modular adapter 50 is provided. In this example, the mechanical interface is comprised of screws 61 that attach and seal the modular adapter 50 to the opening in the vacuum chamber housing 10. The screws 61 provide a force-fit connection between the two components. Tightening the screws compresses the adapter 50 against the housing 10 to create a robust junction. The mechanical force by the screws forces the attachment between the modular adapter 50 and the vacuum chamber housing 10. This force-fit interface ensures that a leak-tight seal is maintained. The screws 61 also function in combination with a gasket or O-ring seal between the adapter and housing surfaces. The compressed gasket provides an air-tight interface.

While only the force-fit screw interface is shown here, the rest of the modular metrology apparatus setup is similar to previous examples and figures described. This includes the arrangement of process modules, sample stage, and other components integrated via the modular adapter architecture.

FIG. 13 schematically illustrates a form-fit mechanical interface between a vacuum chamber housing 10 and a modular adapter 50.

As can be seen in FIG. 13, the mechanical interface provides a form-fit connection, such as a bayonet mount. The vacuum chamber housing 10 has an opening with a specific geometric profile. The modular adapter 50 has a corresponding geometry on its underside that matches the profile of the housing opening. When assembled, the complementing shapes on the housing 10 and modular adapter 50 interlock with one another. This creates a precise form-fit interface between the components that securely attaches the adapter 50 to the housing 10. The geometric interlocking of surfaces prevents lateral motion and separation between the housing 10 and modular adapter 50. The mechanical interfaces can be designed so the adapter 50 detaches from the housing 10 in a controlled way, enabling exchange of modular components.

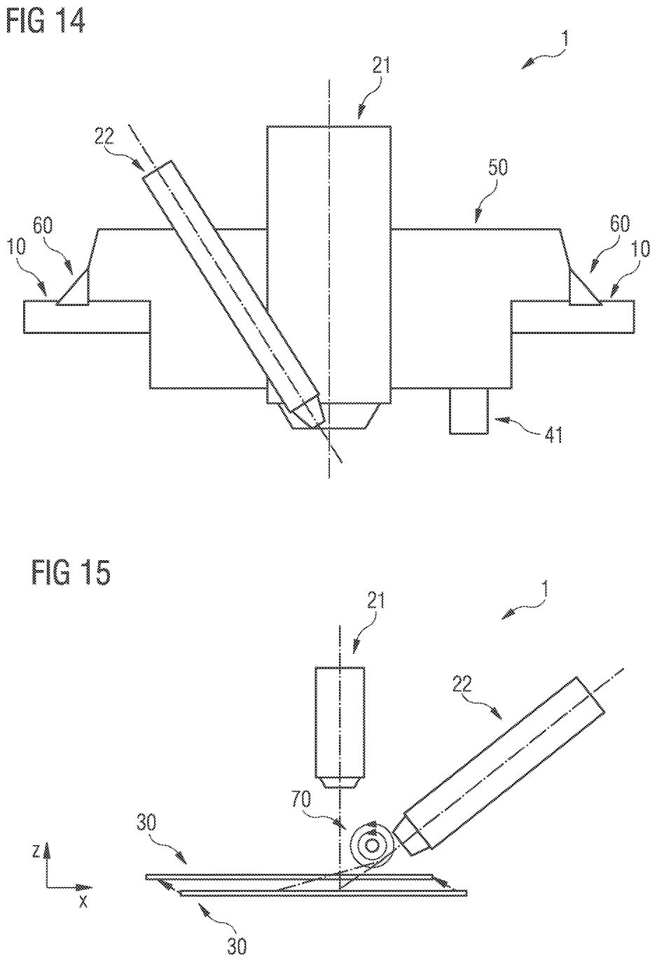

FIG. 14 schematically illustrates a further mechanical interface 60 between a vacuum chamber housing and a modular adapter, according to various examples.

As can be seen in FIG. 14, a material-fit mechanical interface is provided between a vacuum chamber housing 10 and a modular adapter 50. The interface is depicted as weld or glue between the housing 10 and adapter 50. Welding or gluing creates a material-fit connection by fusing or bonding the components together at the molecular level. While welding or gluing helps ensure an air-tight seal for the vacuum environment, it lacks the modularity and configurability of removable attachments like force-fit or form-fit interfaces.

FIG. 15 schematically illustrates a modular metrology apparatus 1 comprising SEM and FIB process modules 21, 22 and a deflection unit 70 integrated into the modular adapter 50, according to various examples.

The deflection unit 70 is fixed to the modular adapter 50 and is configured to deflect the ion beam of the FIB system 22 to adjust its angle of incidence on the sample stage 30. The deflection unit 70 may utilize electromagnetic lenses or electrostatic deflectors, in particular a wire, to influence the path of the FIB beam by a variable magnetic field. By controlling the voltages/currents through the wire the trajectory of the focused ion beam can be steered.

Additionally, the deflection unit 70 can be used to make the FIB beam coincide on the same spot as the SEM beam without moving the sample stage. This enables dual-beam processing like cross-sectioning without moving the sample stage 30.

In other words, the deflection unit 70 utilizes a current-carrying wire that generates a magnetic field to steer the FIB beam. By controlling the current, the strength of the magnetic field can be varied. This allows the coincidence point and incidence angle of the FIB beam on the sample stage 30 to be tuned and adjusted. Stronger magnetic fields provide greater deflection. Steering the beam path may comprise re-focusing the FIB optics to compensate for the increased distance and potential astigmatism introduced by the deflection. To restore the FIB and SEM beams back to a common coincidence point after deflection, the sample stage 30 height may need adjustment. Alternatively, coincidence could be left, and the stage 30 moved in x to scan different areas under the undeflected beams. Retracting the FIB column 22 slightly compared to a fixed coincidence design could provide additional volume needed to incorporate deflectors.

The external deflection unit 70 allows the FIB column 22 to be positioned closer to the SEM column 21 and sample stage 30. Further to mechanically tilting the FIB column 22, the compact deflector steers the beam within the confined space between the SEM process module tip and sample stage. This tighter packing of components enabled by the deflection unit 70 allows an overall reduction in the working distance between the SEM column tip and the sample stage 30. Without the need to accommodate mechanical tilting, the columns 21, 22 can be extended farther forward toward the stage 30. The closely spaced arrangement increases beam intensity and enables advanced simultaneous imaging and processing capabilities. This further advances the modular architecture.

The external deflection unit described herein is presented in an example, that can provide additional beam steering capabilities. However, it should be understood that the deflection unit can be combined with any other features as described in the other figures and various examples. For example with tilted SEM process module arrangements, rotatably or translationally moveable process modules, actuatable process modules, and multi-column configurations. The deflection unit is able to complement and enhance the capabilities provided by other modular components to further decrease working distance, by allowing more compact process module arrangements near the sample and by steering the FIB beam under the tip of the SEM process module of the metrology apparatus. Therefore, the example of FIG. 15 of the deflection unit 70 should not be interpreted as limiting in terms of compatibility with other modular features and arrangements. The modular architecture enables the deflection unit to be integrated as part of various process module configurations.

The invention may further be illustrated by the following examples.

In various examples, the modular metrology apparatus may comprise a modular adapter attached to the mechanical interface of the vacuum chamber housing. The modular adapter may be configurable to receive and seal at least one process module. The modular adapter may comprise at least one process module configured for processing a sample placed on the sample stage. The modular adapter may comprise a mechanical and/or electrical socket for each of the at least one process module.

In general, the modular adapter may comprise, for each of the at least one process module, a socket, or port, or other mounting point, where at least one process module can be installed. The at least one process module may extend from the exterior of the vacuum chamber into the interior, towards the sample stage. This allows the at least one process module to interact with samples within the vacuum chamber. The at least one process module may be in sealed attachment to the modular adapter, such that the vacuum chamber housing and the modular adapter and the at least one process module maintain the sealed environment within the vacuum chamber.

The modular adapter's mechanical interface to the vacuum chamber mechanical interface may enable exchanging of the modular adapter and/or process modules. Process modules may be attached in fixed attachment or removably by fasteners, and/or alignment guides, and/or electrical connectors, and/or and vacuum seals. This allows the metrology apparatus to be reconfigured with different process modules on an exchanged different modular adapter. The entire modular adapter assembly with process modules may be exchangeable and detachable from the vacuum chamber housing. This enables complete modular adapter assemblies, containing integrated process modules, to be swapped as needed to reconfigure the overall metrology apparatus. The mechanical interface around the vacuum chamber opening allows these modular adapter assemblies to be interchangeable.

In various examples, the modular metrology apparatus may further comprise a mounting mechanism of the mechanical interface that allows for detachable and exchangeable attachment of the modular adapter to the vacuum chamber housing.

The modular metrology apparatus may include a mounting mechanism as part of the mechanical interface surrounding the opening in the vacuum chamber housing. This mounting mechanism may enable the modular adapter to be attached and detached in a removable manner. It is to be understood that at least part or the complete mounting mechanism as described may also be included in the corresponding mechanical interface of the modular adapter.

For example, the mounting mechanism could comprise clamps, screws, latches, or other fasteners to securely fix the modular adapter to the vacuum chamber, while also allowing the adapter to be removed and exchanged as needed. The mounting mechanism may also include alignment guides, seals, and connectors to correctly orient and integrate the modular adapter with the vacuum chamber housing.

The ability to detach and exchange the modular adapter provides for reconfiguring the metrology apparatus. By using a removable mounting mechanism as part of the mechanical interface, different modular adapters containing various process modules can be interchanged. This allows the overall system to be optimized and adapted for different inspection, metrology, or analysis procedures by swapping modular adapters.

In various examples, the modular metrology apparatus may further comprise the at least one process module enclosed within the modular adapter, the at least one process module extending from the exterior to the interior of the vacuum chamber housing towards the sample.

The modular metrology apparatus may include the at least one process module installed within and/or surrounded by the modular adapter assembly. When the modular adapter is attached to the vacuum chamber housing, the process module may be enclosed within adapter, such that it does not have contact to the vacuum chamber housing itself.

The at least one process module extends from the outside of the vacuum chamber, where supporting peripherals may be located, towards the inside of the chamber which contains the sample stage. This allows the process module to interact with or process a sample placed on the sample stage inside the vacuum chamber and be easily exchanged together with the modular adapter.

Multiple process modules may be integrated and enclosed within a given modular adapter. Different types of process modules can be exchanged by installing an alternate modular adapter containing the desired components. This modularity and configurability enable optimization of the metrology apparatus for various analytical procedures.

In various examples, the modular metrology apparatus may comprise a mechanical interface that comprises a force-fit connection, and/or a form-fit connection, and/or a material-fit connection. The mechanical interface between the modular adapter and the vacuum chamber housing may utilize various types of connections for a robust attachment. For example, a force-fit connection applies mechanical force or pressure between the components for a secure joint. This could be accomplished using clamps, bolts, interference fits, or other means to create compressive force between the mating parts. A form-fit connection uses shapes and surface geometries to achieve a solid joint. This could involve pins, shoulders, lips, flanges, or other interlocking shapes that prevent movement or separation. A material-fit connection takes advantage of chemical or molecular bonds between the materials. Examples are welds, solders, or adhesives that generate an attachment at the material level. Using one or a combination of these fitting principles allows the mechanical interface to be tailored for a leak-tight and robust junction. The connection must maintain vacuum integrity while also enabling modular flexibility through exchange of adapters.

In various examples, the mechanical interface may utilize a bayonet mount as a form-fit connection between the modular adapter and the vacuum chamber housing. A bayonet mount may use mating components with corresponding indentations and protrusions that interlock when rotated into the engaged position.

For example, the vacuum chamber's mechanical interface may have protruding pins or tabs, while the modular adapter has matching-shaped slots. By aligning the adapter's slots with the chamber's tabs, then twisting to engage the turn-lock mechanism, the components are pulled tight against one another for a secure mount. This allows modular adapters to be rapidly exchanged while also creating a reliable attachment with a vacuum seal. The bayonet mount is one example of a specific form-fit interface implementation.

Other examples of form-fit connections could include threaded fittings, slots, or equivalent geometric couplings that align and interlock the vacuum chamber housing and interchangeable modular adapters.

In various examples, the modular metrology apparatus may further comprise at least one process module selected from the group consisting of a component of the charged-particle scanning system, a Scanning Electron Microscope (SEM), Focused Ion Beam (FIB) system, Gas Injection System (GIS), Energy-Dispersive X-ray spectroscopy (EDX) detector, Secondary Electron Detector, Backscattered Electron Detector, and Infrared Camera.

The modular metrology apparatus may be configured to accommodate various types of process modules within the interchangeable modular adapter assemblies. Examples of process modules that can be integrated include one or more of:

Components of the charged particle beam column, such as lenses, apertures, deflectors, detectors, charged particle columns like a Scanning Electron Microscope or Focused Ion Beam, auxiliary detector, or analysis components like a Gas Injection System, EDX detector, or electron detectors, complementary detector modules such as an Infrared Camera.

This allows the metrology apparatus to be optimized for diverse inspection and analysis capabilities by selecting the desired process modules. Modular adapters can be pre-configured with different sets of process tools or analytics to adapt the system as needed. By accommodating modular swapping of a range of process modules, the metrology apparatus provides flexibility and customizability for various metrology applications.

One or more other process modules that could be integrated into the modular metrology apparatus, which could be configured to detect, analyze, or measure the sample or process parameters within the vacuum chamber. Some examples include an Optical microscope to provide visual inspection of the sample with high resolution and a variety of illumination modes, a Laser scanning microscope to enable confocal optical imaging and surface profiling of the sample, Spectrometry modules such as FTIR, Raman, or UV-vis spectrometers for chemical characterization and composition analysis, an Ellipsometer to measure optical properties and film thickness, Stress measurement sensors to determine residual stress in structures via strain gauges or other techniques, a Hall effect sensor to measure electrical properties of semiconductor materials, a Stylus profilometer to profile surface topography by dragging a fine stylus across the sample, an Interferometer to measure changes in position and distance, a Mass spectrometer to analyze composition by ionizing and sorting chemical species based on mass, Gas analysis modules to measure partial pressures and detect leaks using residual gas analyzers, Thermal sensors to determine temperature or heat flow of the sample, and Nanomanipulators to precisely position and manipulate nanoscale samples. The modular design allows any combination of these detectors, sensors, and analytical components to be integrated as process modules for comprehensive sample characterization.

In various examples, the modular metrology apparatus may comprise a modular adapter configured to receive two or more, for example three or more, different process modules. The modular adapter assembly may be designed to accommodate multiple process modules simultaneously. By integrating more than one type of process module, the capabilities of the metrology apparatus can be expanded. For example, the modular adapter could contain both a scanning electron beam column and a focused ion beam column. This would provide the ability to perform electron and ion beam imaging, ablation, deposition, and other techniques on a single adapter. Additional process modules like specialized detectors could also be included.

In various examples, the at least one process module comprises a Scanning Electron Microscope (SEM). The modular metrology apparatus may include a scanning electron microscope (SEM) as one of the interchangeable process modules. The SEM process module may comprise one or more of an electron column assembly containing an electron source, lenses, deflectors, and detectors to generate a focused electron beam. This electron beam can be raster scanned across the sample surface to create images and maps based on the detected signals. The modular adapter may fully contain and integrate the SEM column and associated components. The SEM can be exchanged in or out in different spatial configurations as needed by exchanging modular adapters, providing flexibility to reconfigure the metrology apparatus for electron microscopy. Exchanging modular adapters allows the SEM to be exchanged with other process modules to reconfigure the metrology apparatus for electron microscopy analysis. The SEM enables high-resolution imaging, metrology, defect review, and other analytical techniques on samples inside the vacuum chamber.

In various examples, the modular metrology apparatus may further comprise a modular adapter configured for a tilted orientation of the SEM source column relative to a z-axis of a machine coordinate system defined by a default setting of the sample stage. The modular adapter may tilt or angle the SEM column at an offset relative to the sample stage's vertical z-axis. The SEM column may be intentionally offset at an oblique angle, such as 10-30 degrees, from the z-axis. This allows the electron beam to strike the sample surface at an angle instead of perpendicularly. The tilt mechanism could use a pivoting or linear offset stage integrated into the modular adapter assembly. Tilting the SEM column provides flexibility in positioning the beam for angle-resolved imaging, 3D tomography, sidewall imaging, and optimized detection geometries. This allows the electron beam to strike the sample at an oblique or side-angle incidence instead of perpendicular to the sample surface. Tilting the column provides flexibility in how the SEM interrogates the sample.

In various examples, the modular adapter may further comprise least two process modules comprising a source column of a Scanning Electron Microscope (SEM) and a beam emitter of a Focused Ion Beam (FIB) system. The modular adapter may integrate both an SEM column and an FIB column together. The modular adapter may integrate both an SEM column and a focused ion beam (FIB) column together within the same adapter. This provides combined electron and ion beam capabilities in a single modular configuration. The FIB process module may comprise one or more of an ion source, beam optics, gas injection, and detectors tailored for ion beam machining and imaging. The combined SEM and FIB columns allow the metrology apparatus to perform operations such as high-resolution cross-sectioning by FIB milling paired with SEM imaging. Swapping to an SEM-FIB modular adapter adapts the system for correlative, multi-modal electron, and ion beam analysis. This provides combined electron and ion beam capabilities in a single modular configuration. The adapter can for example be exchanged to alternate between SEM-only, FIB-only, or combined SEM-FIB operation in various and/or varying spatial configurations, in combination with other process modules as described above.

In various examples, the modular metrology apparatus may further comprise a Laser Interferometer System with a reference mirror integrated into the modular adapter, said Laser Interferometer configured to measure the distance between the modular adapter and the sample stage. The interferometer uses a laser directed at a reference mirror integrated with the adapter to monitor distance by interference patterns. A laser interferometer module may be incorporated to precisely measure relative positioning between the modular adapter and the sample stage. This uses an integrated reference mirror to reflect the interferometer laser for distance measurements and position control feedback.

In various examples, the modular metrology apparatus may further comprise a reference mirror recessed within the modular adapter relative to the at least one process module, wherein the tip of the at least one process module has the forward-most position towards the sample stage. This allows the columns to be extended forward closer to the sample stage without interfering with the laser path. Since the process modules need to be as close to the sample as possible, recessing the reference mirror removes a potential obstacle to minimize working distances. A recess of, e.g., more than 5 mm allows unimpeded access for angled or tilted process modules while maintaining position reference. The reference mirror may be placed in a recessed position so that the process module tips extend further towards the sample stage. This allows the closest possible positioning of the electron/ion columns or other process modules for maximum flexibility.

In various examples, the modular metrology apparatus may further comprise a Scanning Electron Microscope (SEM) configured with a working distance of less than 5 mm between the tip of the source column and the sample stage. The modular adapter may accommodate an SEM column that is capable of achieving small working distances between its lower tip and the sample stage. For example, working distances of less than 5 mm could be realized. This allows the SEM to be positioned close to the sample for improved resolution and beam intensity. Reduced working distances can also enable special modes like low voltage scanning for ultrasensitive imaging. To achieve sub-5-mm working distances, the mechanical and electrical design must avoid collisions and field interactions between the column and the stage. The modular adapter provides an integrated solution to position the SEM column within this tight constraint while scanning across the sample. The adaptable modular architecture facilitates use of unconventional compact SEM configurations.

In various examples, the modular metrology apparatus may further comprise a modular adapter having a turret shape comprising a rotatable structure to enable variable positioning of the at least one process module relative to the sample stage. The modular adapter may utilize a turret design to allow rotation of process modules around the sample stage. In a turret configuration, the adapter has a rotating section that can pivot to precisely aim the attached process modules. For example, the adapter may contain multiple columns or tools at fixed ports around the turret. By rotating the turret section, different process modules can be indexed into alignment with the sample. This enables variable positioning without breaking vacuum. The rotatable turret provides flexibility to redirect process modules to approach the sample from different angles. Discrete rotational increments allow reproducible positioning. This approach can enable unconventional geometries while maintaining modular exchangeability of the adapter.

In various examples, the modular metrology apparatus may further comprise at least one process module translationally and/or pivotally movable relative to the modular adapter by at least one actuator, in order to enable positioning of the process module relative to the sample stage. The modular adapter may allow integrated movement of process modules using actuators. These actuators can translate (linearly position) the process modules and/or pivot (rotate) the process modules relative to the sample stage. For example, a process module could be mounted on a controllable linear slide or rotary stage. This would enable precise x-y-z positional adjustment and/or angular tilting of the column or tool relative to the sample. Actuators may be used to align process modules to calibration targets, optimize working distances, raster scan the beam, implement angular positioning, and otherwise tailor the geometry between module and sample. The modular adapter provides an integrated mechanical structure to incorporate adjustable actuators. This allows flexible positioning of modules after the adapter is installed, enhancing modularity and configurability. Actuators expand the range of possible process module orientations.

In various examples, the modular metrology apparatus may further comprise an external deflection unit fixed to the modular adapter and configured to deflect the ion beam of the Focused Ion Beam (FIB) system to adjust the angle of incidence on the sample stage. An external deflection unit may be incorporated into the modular adapter to manipulate the trajectory of the ion beam within the FIB column. This deflection unit is outside of the FIB column itself and provides additional control of the beam angle. For example, the unit may be realized by one or more of a charged wire, or an electromagnetic lens placed into the beam path. By controlling voltages or currents, the ion beam can be deflected to change its incidence angle on the sample stage. This enables variable beam approach angles, coincidence positioning with other beams, off-normal milling, and compensation for stage drift. External manipulation simplifies altering ion beam geometry. The fixed integration into the adapter makes the deflector modular along with the FIB column.

The external deflection unit may comprise an electromagnetic or electrostatic lens configured to deflect the ion beam of the Focused Ion Beam (FIB) system to adjust the angle of incidence on the sample stage. The external ion beam deflection unit may utilize charged electromagnetic lenses or electrostatic deflectors to influence the path of the beam. By controlling the lens voltages or currents, the trajectory of the focused ion beam can be steered and adjusted as desired. This allows the angle of the beam as it impacts the sample surface to be controlled independently of the FIB column alignment. In various examples, the external deflection unit may comprise a conductor traversing the ion beam of the Focused Ion Beam (FIB) system to generate a magnetic field that deflects the ion beam to adjust the angle of incidence on the sample stage. The ion beam deflection unit may use a current-carrying wire or other conductor placed into the beam path to create a magnetic field. As the charged ion beam passes through this field, its trajectory will curve according to the right-hand rule of electromagnetism. Varying the current in the wire allows adjustable control of the ion beam deflection angle and incidence on the sample stage. The external deflection unit may be configured to deflect the ion beam of the Focused Ion Beam (FIB) system to adjust the angle of incidence to align with a common incidence point on the sample stage as the electron beam of a Scanning Electron Microscope (SEM). The ion beam deflector may be used to make the FIB and SEM beam coincide on the same point on the sample. By deflecting the ion beam, it can be made to hit the sample at the same location as the stationary electron beam. This enables certain dual-beam operations like cross-sectioning to be performed without sample motion. Adjustable ion beam deflection allows flexible coincidence positioning of the two beams.

In various examples, the modular metrology apparatus may be a charged-particle microscope system, or a Scanning Electron Microscope (SEM) system, or in some examples a combined SEM-FIB system optionally with further processing modalities provided by further process modules.

In various examples, the vacuum chamber housing, the modular adapter, and the at least one process module mechanically engage to form a sealed inner space of the vacuum chamber. The vacuum chamber housing, adapters, and process modules seal together to create a vacuum environment needed for charged particle beams. The mechanical engagement between these removable components forms a closed inner space that can be pumped down to vacuum conditions necessary for electron or ion beam operation, sample inspection, and processing.

In various examples, the mechanical interface may comprise a release mechanism, for example a quick-release mechanism, for detachment and reattachment of the modular adapter. The mechanical interface may incorporate one or more precision alignment features, e.g., kinematic mounts or pins or a keyed design to ensure repeatable positioning of the modular adapter.

For example, the mechanical interface may employ a standardized design compatible with various modular adapters, for example a flange design. In various examples, a standardized interface may allow for interchangeability between different adapter configurations without modification to the vacuum chamber housing.

The modular adapter may be configured to receive and/or hold multiple, i.e. two or more, or three or more, different process modules. For example, it may position the multiple process modules in a predefined spatial arrangement relative to each other. For example, it may define the relative position of the process modules to each other. In various examples, the spatial configuration of the process modules may be predetermined by the adapter.

The modular adapter for the metrology apparatus may be formed as a separate component from the at least one process module and configured to be attached to the mechanical interface of the vacuum chamber. The modular adapter may comprise a corresponding mechanical interface corresponding to the mechanical interface of the vacuum chamber housing. The mechanical interface may be configured for releasable attachment of the modular adapter. The modular adapter may be configured to be an intermediate mechanical component between the one or more process modules and the mechanical interface of the vacuum chamber housing.

The mechanical interface may provide a unified and/or standardized mechanical and/or electrical and/or fluid connection between the one or more process modules and the vacuum chamber. For example, the one or more process modules may be arranged as an integrated unit(s) within the adapter in the metrology system. In various examples, they may be exchanged collectively by releasing the interface between the modular adapter and the housing. Thereby, the integrated design of the adapter may enable closer proximity of different analytical tools than possible with separate mounting positions on the vacuum chamber housing.

Different adapters with varying configurations of one or more process modules may be interchangeable. In various examples, they may utilize the same standardized mechanical and/or sealing interface to the vacuum chamber housing. Accordingly, switching between different analytical system configurations may be achieved by simply exchanging the adapter.

The modular adapter may on one side be attached to the one or more process modules, and on the other side to the vacuum chamber housing. The modular adapter may surround each of the one or more process modules. The modular adapter may provide the vacuum sealing as a single interface to the vacuum chamber housing. This may eliminate the need for individual sealing of each module directly to the housing.

Although the invention has been shown and described with respect to certain preferred embodiments, equivalents and modifications will occur to others skilled in the art upon the reading and understanding of the specification. The present invention includes all such equivalents and modifications and is limited only by the scope of the appended claims.

For illustration, above, various examples have been disclosed in which a dwell time is adjusted between acquisition of images having low SNR and high SNR, respectively. Alternatively, or additionally to adjusting the dwell time, it would also be possible to adjust different imaging parameters impacting the SNR, e.g., particle flux/particle current.

What is claimed is:

1. A modular metrology apparatus, comprising:
a vacuum chamber housing having an opening with a mechanical interface configured for sealed attachment of a modular adapter;
a sample stage located inside the vacuum chamber housing; and
at least one charged-particle scanning system, each of the at least one charged-particle scanning system being configured for scanning a respective beam of charged particles across the sample stage.

2. The modular metrology apparatus of claim 1, further comprising:
a modular adapter attached to the mechanical interface, the modular adapter comprising at least one process module configured for processing a sample placed on the sample stage.

3. The modular metrology apparatus of claim 2, wherein the at least one process module comprises at least a source column of the at least one charged-particle scanning system.

4. The modular metrology apparatus of claim 3, wherein the modular adapter is configured for a tilted orientation of the source column relative to a z-axis of a machine coordinate system defined by a default setting of the sample stage.

5. The modular metrology apparatus of claim 1,
wherein the mechanical interface between the modular adapter and the vacuum chamber housing extends along the perimeter of the opening, and comprises a mounting mechanism allowing for releasable attachment of the modular adapter to the vacuum chamber housing.

6. The modular metrology apparatus of claim 1, wherein the at least one process module is enclosed within the modular adapter, extending from the exterior to the interior of the vacuum chamber housing towards the sample.

7. The modular metrology apparatus of claim 1, wherein the mechanical interface comprises a force-fit connection.

8. The modular metrology apparatus of claim 1, wherein the at least one process module comprises at least two process modules, wherein the at least two process modules are selected from the group consisting of a Scanning Electron Microscope (SEM), Focused Ion Beam (FIB) system, and Gas Injection System (GIS), Energy-Dispersive X-ray spectroscopy (EDX) detector, Secondary Electron Detector, Backscattered Electron Detector, and Infrared Camera.

9. The modular metrology apparatus of claim 1, wherein the at least one process module comprises at least two process modules comprising a source column of a Scanning Electron Microscope (SEM) and a beam emitter of a Focused Ion Beam (FIB) system.

10. The modular metrology apparatus of claim 1, further comprising a Laser Interferometer System with a reference mirror integrated into the modular adapter, said Laser Interferometer configured to measure the distance between the modular adapter and the sample stage, wherein the reference mirror is recessed within the modular adapter relative to the at least one process module, wherein the tip of the at least one process module has the forward-most position towards the sample stage.

11. The modular metrology apparatus of claim 1, wherein the at least one process module is translationally movable relative to the modular adapter in a vertical direction and/or a lateral direction by at least one actuator, in order to enable positioning of the process module relative to the sample stage.

12. The modular metrology apparatus of claim 1, wherein the at least one process module is pivotally movable relative to the modular adapter by at least one actuator, in order to enable angular positioning of the process module relative to the sample stage.

13. The modular metrology apparatus of claim 9, further comprising an external deflection unit fixed to the modular adapter and configured to deflect the ion beam of the Focused Ion Beam (FIB) system to adjust the angle of incidence on the sample stage.

14. The modular metrology apparatus of claim 13, wherein the external deflection unit comprises a conductor traversing the ion beam of the Focused Ion Beam (FIB) system to generate a variable magnetic field that deflects the ion beam to adjust the angle of incidence on the sample stage.

15. The modular metrology apparatus of claim 13, wherein the external deflection unit is configured to deflect the ion beam of the Focused Ion Beam (FIB) system to adjust the angle of incidence to align with a common incidence point on the sample stage as the electron beam of a Scanning Electron Microscope (SEM).

16. The modular metrology apparatus of claim 2, wherein the mechanical interface between the modular adapter and the vacuum chamber housing extends along the perimeter of the opening, and comprises a mounting mechanism allowing for releasable attachment of the modular adapter to the vacuum chamber housing.

17. The modular metrology apparatus of claim 2, wherein the at least one process module is enclosed within the modular adapter, extending from the exterior to the interior of the vacuum chamber housing towards the sample.

18. The modular metrology apparatus of claim 2, wherein the mechanical interface comprises a force-fit connection.

19. The modular metrology apparatus of claim 2, wherein the at least one process module comprises at least two process modules, wherein the at least two process modules are selected from the group consisting of a Scanning Electron Microscope (SEM), Focused Ion Beam (FIB) system, and Gas Injection System (GIS), Energy-Dispersive X-ray spectroscopy (EDX) detector, Secondary Electron Detector, Backscattered Electron Detector, and Infrared Camera.

20. The modular metrology apparatus of claim 2, wherein the at least one process module comprises at least two process modules comprising a source column of a Scanning Electron Microscope (SEM) and a beam emitter of a Focused Ion Beam (FIB) system.
